(19) United States
(12) Patent Application Publication
(10) Pub. No.: US 2017/0098934 A1
(43) Pub. Date: Apr. 6, 2017

(54) SURGE ARRESTER OF AN AIRFIELD LIGHTING SYSTEM AND A SECONDARY CIRCUIT OF AN AIRFIELD LIGHTING SYSTEM

(71) Applicant: EFLA OY, Porvoo (FI)

(72) Inventors: Mika Laukkanen, Porvoo (FI); Jaakko Einovaara, Porvoo (FI)

(21) Appl. No.: 15/286,713

(22) Filed: Oct. 6, 2016

(30) Foreign Application Priority Data
Oct. 6, 2015 (EP) 15188564.7

(51) Int. Cl. H02H 9/04; H02H 7/04; H02H 1/04; H05K 5/06

(52) U.S. Cl. CPC H02H 9/045; H05K 5/06; H02H 7/04; H02H 1/04

(57) ABSTRACT

A surge arrester of an airfield lighting system, wherein the airfield lighting system includes a primary circuit having a plurality of transformers with primary windings and secondary windings, the primary windings of the transformers being connected in series in the primary circuit and at least one of the secondary windings of the transformers is adapted to feed electric power to a secondary circuit having an illumination device of the airfield lighting system, wherein the surge arrester includes a hermetically sealed enclosure for protecting the circuitry of the surge arrester and connectors for electrically connecting the surge arrester to the secondary circuit, the surge arrester being adapted to provide a low impedance current path to ground for excessive voltages.

### TECHNICAL FIELD

The embodiment relates to airfield lighting systems, and particularly to overvoltage protection of airfield lighting systems.

### BACKGROUND

One important aspect of operation of an airfield or an airport is proper operation of the airfield lighting system or aeronautical ground lighting (AGL). Such lighting system includes approach and threshold lighting, runway lighting and taxiway lighting, for example.

The various components used in lighting are operated in extremely harsh conditions, as the temperatures in the open airfields vary considerably and various chemicals are used in the operation and maintenance of the planes and the airfield. Therefore strict requirements are set to the components of the lighting system. The components are usually installed in pits or cans, but they can be also buried directly into the ground. In normal operation they must be totally resistant for water, ice, kerosene, anti-freeze and defrosting liquids, etc. at operational voltages up to 5 kV.

The housing of the components must also be resilient enough to work as shock-absorber and protect the various components. Airports usually expect the life span of transformers and connectors to be 10-20 years in these very demanding circumstances.

In airfield lighting systems, there are two types of feed for lighting fixtures located along a runway or a taxiway: series feed and parallel feed. With the parallel feed a progressive voltage drop occurs from light to light even with bigger cable dimensions. This causes the light illumination levels to vary. For this reason series feed systems are more common in the airfield lighting.

A series circuit fed circuit utilizes a constant current regulator, insulating transformers and lamps specially designed for a rated current. In a series circuit current is fed to a current loop which has primary windings of the insulating transformers connected in series. The secondary windings of the insulating transformers provide a set current to the illumination device. The nominal current in the series feed system circuits is most commonly 6.6 Amperes, but the current may vary.

The primary circuit is supplied by a constant current regulator (CCR) which makes it possible to obtain the rated light intensity of 6.6 A fixtures. The brightness of the lights is controlled by reducing the current usually by 5 different steps. The series circuit, which is thus known as the primary circuit, consists of a single-core cable connecting the separation transformers in series.

The transformers have a twofold function. Firstly, the transformers protect the personal by insulating the secondary circuit from the high voltage of the primary circuit. Secondly, the transformers enable to maintain continuity of the primary circuit when a light in the secondary is out of service. Thus the primary current flows to all the transformers enabling the operation of the intact lights.

The secondary of each insulating transformer is normally connected to a single light by means of a secondary two-core cable or 2 one-core wires. It is also possible to supply several lights with a single transformer when the lights are close to one another. The lamps used in the installations may be, for example halogen, cascade tubes or LED's.

The insulating transformers are furnished with 2 primary cables and one secondary cable with moulded-on connectors. Transformers can be buried near the light but it is preferable for them to be placed housed in an inspection man-holes.

The primary cable, furnished with field-assembled connectors, is connected in segments from one transformer to the next in the same circuit until the circuit forms a loop with outgoing and incoming cables connected to the constant current regulator. The primary cable is typically buried in a trench joining inspection man-holes, between two layers of sand, out of reach of stones or any objects which could damage it.

Although more costly, the use of a cable with a shield is strongly recommended in countries with frequent storms. An unshielded cable must normally be protected from the effects of the weather by means of a bare equipotential earth wire located about 10 cm above it in the trench.

The shield and equipotential wire are connected with the regulator earth connection. On the cables with a shield, the shield is insulated by the protective sheath, and should be connected with earth rods about every 300 m.

The inspection man-holes can be made of welded steel or prefabricated concrete. The latter system is preferable as all corrosion risks are excluded. They should be covered with a steel or reinforced concrete plate. Provision should be made for drainage.

In some cases of runway inset lights, the transformer and the secondary circuit structure are placed under the light itself in a fixture commonly known as a “can”. This solution presents the inconvenience of running the high voltage primary cables under the runway, thus giving significant difficulties of repair in case of failure on those cables. The light installation fixture geometries are standardized and the space under the light is quite small. This limits the maximum size of components that can be connected to the secondary circuit. The installation space in pits and especially in cans is very limited, which makes certain requirements for the physical size of the products.

The secondary cable lead, which consists of cable with usually field-assembled plug and receptacle, or a prefabricated with moulded-on connecting parts, connects the light to the transformer by means of a sealed plug. This connection, running along a trench, in a wireway in the pavement or in a conduit tube, can be made by means of a bipolar cable or two segments of unipolar cable joined on the transformer side, to a KIT plug. These secondary equipment are 1 kV isolated according to requirements given in FAA 150-5345-26D.

Certain climate regions have thunder and lightning more often than other regions. It is known to have surge arresters providing lightning protection in the primary circuit. Such units must withstand the high voltages (up to 5000 V) of the primary circuit which makes the units large in size and quite expensive. The large size prevents the units to be installed in fixtures under the light. If the unit is made inoperable for example by a direct lightning strike the cost of replacing the unit is quite high and also the whole circuit, in the worst case consisting of over 200 AGL-fittings, must be turned off during this operation.

FAA regulations demand that the lights are protected from surge currents. In case of inducted overvoltage the lights should be protected by it's build in surge protection as defined in FAA Engineering Brief No. 67 (Nominal discharge current 8/20 μS of 5 kA).

Due to electrical efficiency and controllability LED's are more and more used as illumination sources in airfield installations. LED light sources require additional circuitry in the secondary circuit and thereby the costs relating to illumination have risen. Further, some diagnostic features including communication and data transmission can be provided in the secondary circuit.

One of the problems associated with the above arrangement is that the protection provided by the installations against surge voltages is somewhat limited. The costs of operation and maintenance of the system increase when the described protection is used in climate condition in which lightning rate is high. The amount of additional circuitry in the secondary circuit adds the maintenance costs if the surge protection is not capable of limiting the voltages and currents efficiently. Further, the mentioned operation downtime is costly as the airports or runways may be closed.

### SUMMARY

An object is to provide surge arrester and a secondary circuit.

The embodiment is based on the idea of providing a hermetically sealed surge arrester with connectors to be installed to the secondary circuit of an airfield lighting installation.

An advantage of the circuit of the embodiment is that the protection provided by the circuit is more efficient in protecting the lighting installations than the known systems. In the known systems, when a surge voltage is applied to the light source or lighting fixture located at the airfield, the surge voltage can spread to the primary circuit and to other lighting fixtures located at the proximity of the source of the surge voltage. With the present embodiment, however, the current originated from a surge voltage is led to the ground at the secondary side of the lighting installation such that the high currents are not causing any substantial damage in other installed lighting fixtures. The known surge arresters of the lighting fixtures are provided as integral parts of the lighting fixtures to protect the lighting fixtures themselves.

The surge arrester of the embodiment enables to protect the primary circuit and the neighbouring secondary circuits from a lightning strike that hits a lighting fixture. If a lightning strikes to an illumination device of a secondary side, a high current flows through the isolation transformer to the primary circuit. If the primary circuit is seriously damaged, the constant current regulator may not be able to provide desired current to the primary circuit, and thereby whole illumination system will be out of order.

As the voltage of the secondary circuit of the lighting system is considerably lower than in the primary circuit, the surge arrester can be made smaller than the ones used in the primary circuit. The smaller size enables to position the surge arresters in close proximity to the light sources and other circuitry relating to the light sources. The surge arresters of the embodiment can be placed to the cans or pits together with the lighting fixtures.

With the surge arrester of the embodiment, especially the protection of the light sources and the circuitry relating to the light sources is increased. Modern air field lighting systems are employing LED's as light sources in the illumination due to the advantages obtained with LED technology. LED light sources and the required circuitry are quite expensive when compared to traditional incandescent halogen lights, for example. Further, the secondary circuit may also include electronic circuits that are used for monitoring or controlling of the operation of the light source. The secondary circuit with the surge arrester protects also the other components and the circuitry than the light source. The secondary circuit of the embodiment thus provides a cost efficient protection for the installed components as installation space of the surge arresters is smaller than with the known primary side surge arresters. Further, the increased protection decreases the maintenance costs as the costly light sources and related circuitry are kept in proper operation for longer periods.

As the surge arrester of the embodiment is a small-sized stand-alone passive unit, it can be installed to existing lighting installations. The surge arrester provides a straight current path through the component when voltages of the secondary circuit are in allowable range. This means that all the signals and electrical power can pass through the surge arrester without any modifications to the waveform. Further, as the surge arrester of the embodiment comprises connectors, the device can be easily attached to existing installations.

### BRIEF DESCRIPTION OF THE DRAWINGS

In the following the invention will be described in greater detail by means of preferred embodiments with reference to the accompanying drawings, in which

FIG. 1 is shows a simplified circuit diagram of an airfield lighting system with series feed;

FIGS. 2 and 3 shows examples of secondary circuits with the surge arrester;

FIG. 4 shows an example of a surge arrester circuit; and

FIG. 5 illustrates a schematic representation of a circuit board of the surge arrester having a shape designed to prevent the surge according to an embodiment.

### DETAILED DESCRIPTION

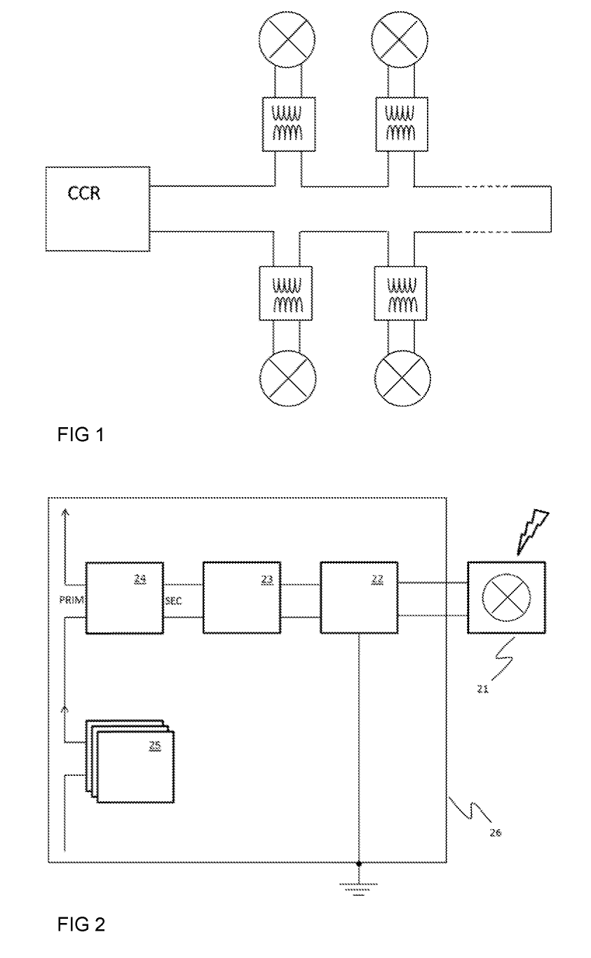

FIG. 1 is shows a circuit of the type used commonly in airfield lighting system. A constant current regulator feeds constant current to a loop which is formed of series connection of primary windings of separation transformers and cabling connecting the transformers. The constant current regulator adjusts its output voltage such that desired current will flow via the primary circuits of the transformers. The secondary windings of the transformers provide power to secondary circuits which are equipped with light sources or illumination devices, such as LED's.

According to the present embodiment, the surge arrester comprises a hermetically sealed enclosure for protecting the circuitry of the surge arrester and connectors for electrically connecting the surge arrester to the secondary circuit. The surge arrester is adapted to provide a low impedance current path to ground for excessive voltages. The surge arrester of the embodiment is connectable with the provided connectors electrically to the illumination device for providing a low impedance path to ground from the secondary circuit for excessive voltages.

As shown in FIG. 2 a surge arrester of the embodiment 22 is connected to the electric conductors or feed wires feeding the light source 21. In operation within normal operation voltages of the system, the surge arrester 22 does not affect the power feed to the light source 21 and provides thus a path for all the signals entering the secondary circuit. That is to say that a zero impedance current path is provided in the secondary circuit for the power feed to the light source by the surge arrester in normal operation of the secondary circuit.

FIG. 4 shows an embodiment of a surge arrester that is suitable for use in the secondary circuit of the airfield lighting system. The circuit employs three gas discharge tubes (GDT) F1, F2, F3 or similar components that change from high impedance state to low impedance state depending on the voltage over the component. Two of the three GDT's are connected in series between the operational power feed conductors and the center point between the series connection is connectable to ground. One of the protective components is connected directly between the power feed conductors. When excessive voltage is built across the power feed conductors, the impedance of the protective components drops, and current is led to ground. According to an embodiment, the surge arrester comprises also a thermal relay (not shown in FIG. 4). The thermal relay may be connected between the power feed conductors before the connection of the GDT's from the connector J1 and J4. The thermal relay may protect the surge arrester against excessive or undesired heating that might damage the surge arrester. For example, the surge caused by the lightning may cause undesired excessive heating, even with the protective GDT components and appropriate grounding. The thermal relay controls the heating with desired tolerances with respect to the materials and usability of the surge arrester. According to an embodiment, the GDT's may be connected to the circuit boards directly without soldering lumps.

FIG. 2 also shows a single lamp control module (SLCM) 23 connected at the input of the secondary circuit, that is, at the output of the secondary winding of the transformer 24. Single lamp control module 23 is a device that may control the light source in desired manner and monitor the operation condition of the light source 21. SLCM may include electronic circuits that are arranged to detect information coded to the supplied voltage or current. Further, SLCM may also transmit information relating to the operation of the light source to centralized control system.

FIG. 2 shows also other transformers 25 connected to the primary circuit. It is clear, that the other transformers may also include secondary circuits that are similar to that described in more detail. In FIG. 2 a lighting stroke is shown to hit the light source 21. In such situation, a high current flows through the light source and partial current flows via the conductor towards the surge arrester 22. When the voltage in the surge arrester increases, the impedance of the surge arrester drops dramatically and the current is led through the surge arrester to ground. In FIG. 2 the installations are shown to be situated in a cable pit 26 which is grounded, and the surge arrester is connected to ground by connecting the grounding terminal of the surge arrester to the cable pit.

Although the light source will probably be destroyed by the direct lighting strike, the surge arrester will protect other components in the secondary circuit. In addition to protecting the secondary circuit, the surge arrester protects also the isolation transformer, primary circuit and other secondary circuits. Thus the surge arrester operates to protect the power feed whereas typical surge arrester installations are protecting single loads.

When lightning strikes near to an installation of the secondary circuit, overvoltages will be induced to the wires of the secondary circuit. Similarly as in the FIG. 2, the surge arrester of the embodiment will operate to short-circuit the current to the ground and thereby alleviate the influences of the overvoltage.

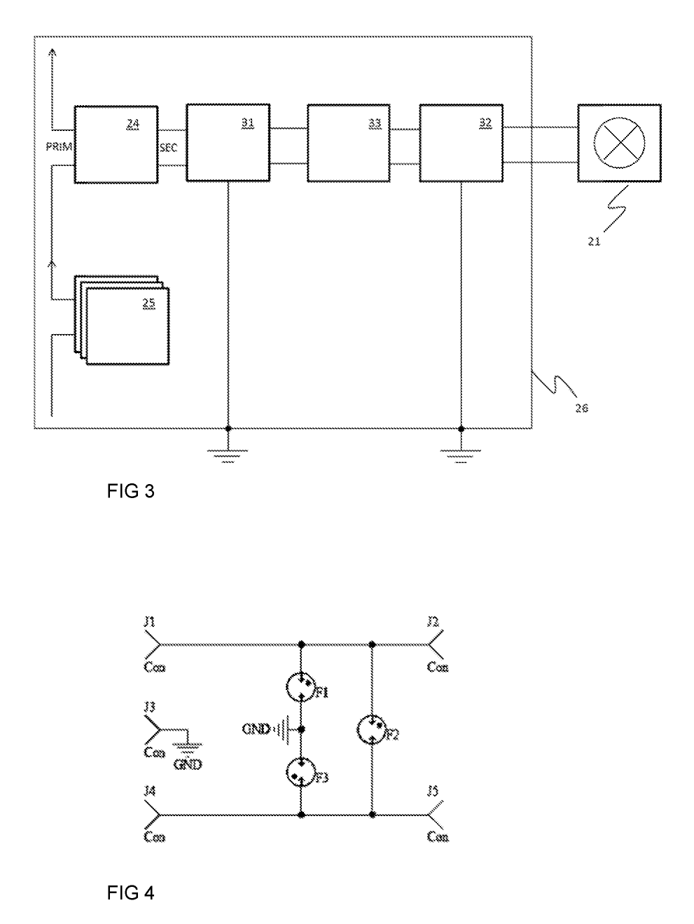

FIG. 3 shows a secondary circuit with two surge arresters 31, 32 of the embodiment. The surge arresters are shown to be installed on both sides of the single lamp control module 33 in the secondary circuit of an airfield lighting installation. When using two surge arresters as shown, the protection of the installation is further increased. The surge arrester 31 connected at the input of the secondary circuit helps in minimizing the voltages or currents arriving from the primary side. In case a surge current enters the secondary side of the transformer 24 due to abnormal voltage in the primary side of the transformer, the surge arrester connected at the input of the secondary circuit blocks the over voltage and thereby protects the single lamp control module 33 or any other installation in the secondary circuit. If the high current or voltage still proceeds towards the light source, the second surge arrester 32 will operate to protect the light source installation.

The installation of FIG. 3 increases the protection also in cases when surge voltage is applied to the light source or to the circuitry of the light source. The surge arrester 32 installed between the single lamp control module 33 and the light source protects the installation as in the example of FIG. 2. The other surge arrester 31 adds protection by further protecting the transformer and the primary circuit of the transformer by shorting voltages that could still harm the primary circuit and the transformer.

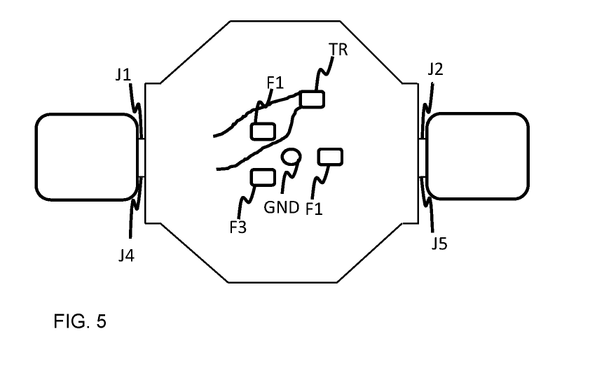

FIG. 5 illustrates a schematic representation of a circuit board of the surge arrester having a shape designed to prevent the surge according to an embodiment. The surge arrester comprises the GDTs F1,F2,F3 and the thermal relay TR. The thermal relays may be connected to the circuit board by wires. Ground GND is illustrated in the middle of the circuit board. The shape of the circuit board of the surge arrester is configured to prevent the surge, for example caused by the lightning, to escape the circuit board undesirably. Instead of, for example, a typical rectangular circuit board, the circuit board of FIG. 5 is rounded or circularly shaped so that peak electric potential points may be reduced in the design. The electric potential may be more evenly distributed within the shape of the board, thereby reducing the possible on undesired surges from the board.

As mentioned, the surge arrester of the embodiment comprises connectors with which the surge arrester can be installed to the secondary circuit. The connectors are preferably in a form of standardized connectors enabling to attach the surge arrester to standard installations.

According to the embodiment, the surge protector is hermetically sealed. The hermetic sealing means in practice that the surge protector of the embodiment is fabricated to withstand the airfield environment including wide range of temperatures and different chemicals. According to an embodiment, the hermetically sealed structure comprises low pressure moulded inner structure which encloses the circuitry in a printed circuit board. The structure further comprises an outer surface producing the hermetically sealed casing for the circuit. The low pressure moulded inner structure provides mechanical strength against mechanical forces and vibrations for the physical device while the outer surface provides the hermetic sealing of the device.

The surge protector of an embodiment may be provided without wires extending from the casing of the device. In such a case the connectors are directly attached to the circuit board or wired to the circuit board inside the protective casing. The connectors typically consist of a male and a female connectors and an earthing connector which can be wired to a grounded spot during installation of the device.

The connectors or interfaces are also manufactured in fully watertight manner such that when connected to mating connectors, the outer material of the enclosure of the surge protector extends over the point of connection. The connectors enable to connect the surge protector to a light source, possible single light control module or other similar electronic device, the secondary of the transformer or to another similar surge protector.

The surge protector of an embodiment build using gas discharge tubes can withstand multiple instances of surge voltages. In a direct lightning hit to an illumination device the amount of energy is capable of destroying the illumination device although some of the current is led directly to ground using earth termination of the lamp. In case the surge protector is also destroyed by a surge voltage, the surge protector has operated to limit the influence of the surge voltage. As the surge protector of the embodiment is situated in the secondary circuit, the device can be safely changed to a new one without interrupting the operation of other light sources.

It will be obvious to a person skilled in the art that, as the technology advances, the inventive concept can be implemented in various ways. The invention and its embodiments are not limited to the examples described above but may vary within the scope of the claims.

1. A surge arrester of an airfield lighting system, the airfield lighting system comprising:
a primary circuit having a plurality of transformers with primary windings and secondary windings, the primary windings of the plurality of transformers being connected in series in the primary circuit and at least one of the secondary windings of the plurality of transformers is adapted to feed electric power to a secondary circuit having an illumination device of the airfield lighting system,
the surge arrester comprising:
a hermetically sealed enclosure for protecting the circuitry of the surge arrester; and
connectors for electrically connecting the surge arrester to the secondary circuit, the surge arrester being adapted to provide a low impedance current path to ground for excessive voltages.

2. A surge arrester according to claim 1, wherein the secondary circuit further comprises a lamp control module connected at an input of the secondary circuit, and wherein the surge arrester is adapted to protect the lamp control module by providing a low impedance current path for excessive voltages that are applied to the illumination device or to circuitry of the illumination device.

3. A surge arrester according to claim 1, wherein the surge arrester is adapted to protect a transformer and the primary circuit for excessive voltages that are applied to the illumination device or to circuitry of the illumination device.

4. A surge arrester according to claim 1, wherein the surge arrester comprises an electric circuit comprising a plurality of gas discharge tubes mounted on a printed circuit board.

5. A surge arrester according to claim 4, wherein the electric circuit of the surge arrester provides a low impedance current path through the surge arrester for operating power of the illumination device.

6. A surge arrester according to claim 4, wherein the connectors comprise a pair of input terminals, a pair of output terminals, and a grounding terminal, and wherein the electric circuit comprises direct currents paths between the respective input terminals and output terminals, a series connection of gas discharge tubes connected between the current paths, a gas discharge tube connected in parallel with the series connection of the gas discharge tubes, and the grounding terminal is connected to a circuit in a point between the series connection of gas discharge tubes.

7. A surge arrester according to claim 1, wherein the hermetically sealed enclosure comprises a low pressure moulded inner structure enclosing the circuitry of the surge arrester and an outer structure enclosing inner structure and providing a hermetically sealed casing.

8. A surge arrested according to claim 1, further comprising a thermal relay configured to prevent a surge arrested from undesired excessive heating.

9. A surge arrester according to claim 4, wherein the plurality of gas discharge tubes are directly connected to the printed circuit board without soldering lumps.

10. A surge arrester according to claim 1, wherein the surge arrester further comprises an electric circuit mounted on a printed circuit board, and wherein a shape of the printed circuit board is rounded.

11. A secondary circuit of an airfield lighting system, comprising:
a surge arrester, wherein the airfield lighting system comprises a primary circuit having a plurality of transformers with primary windings and secondary windings, the primary windings of the plurality of transformers being connected in series in the primary circuit and at least one of the secondary windings of the plurality of transformers is adapted to feed electric power to a secondary circuit having an illumination device of the airfield lighting system, the surge arrester comprising:
a hermetically sealed enclosure for protecting circuitry of the surge arrester; and
connectors for electrically connecting the surge arrester to the secondary circuit, the surge arrester being adapted to provide a low impedance current path to ground for excessive voltages.
